(19) United States
(12) Patent Application Publication
(10) Pub. No.: US 2026/0123384 A1
(43) Pub. Date: Apr. 30, 2026

(54) GUARD RING STRUCTURE WITH DISCHARGING STRUCTURE

(71) Applicant: Taiwan Semiconductor Manufacturing Company, Ltd., Hsin-Chu (TW)

(72) Inventors: Yang-Hsin Shih, Hsinchu City (TW); Kuan-Hsun Wang, Hsinchu City (TW); Chih Hsin Yang, Zhubei City (TW); Mao-Nan Wang, Kaohsiung City (TW); Chih-Chieh Chang, Hsinchu (TW); Yun-Sheng Li, Hsinchu (TW)

(21) Appl. No.: 19/068,257

(22) Filed: Mar. 3, 2025

Related U.S. Application Data
(60) Provisional application No. 63/711,417, filed on Oct. 24, 2024.

(51) Int. Cl. H01L 23/522; H01L 21/768; H01L 23/48; H01L 23/528; H10D 89/60

(52) U.S. Cl. CPC H10W 20/42; H10D 89/611; H10W 20/023; H10W 20/20; H10W 20/427

(57) ABSTRACT

A semiconductor structure includes a substrate, a dielectric structure including a plurality of dielectric layers, a ring structure disposed in the substrate and the dielectric structure, and a via structure extending lengthwise along a vertical direction and in a region surrounded by the ring structure. The plurality of dielectric layers include a plurality of frontside dielectric layers disposed on a front side of the substrate and a plurality of backside dielectric layers disposed on a back side of the substrate. The ring structure includes metal features disposed in the plurality of dielectric layers of the dielectric structure. In a top view, the ring structure has a ring pattern, and one of the metal features extends laterally beyond outer sidewalls of the ring pattern to be connected to a diode or a conductive via. The conductive via is connected to a first reference voltage.

### PRIORITY DATA

This application claims priority to U.S. Provisional Patent Application No. 63/711,417, filed Oct. 24, 2024, which is incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor structure, according to one or more aspects of the present disclosure.

FIGS. 2, 3, 5, 6, and 7 illustrate fragmentary cross-sectional views of an exemplary semiconductor structure during various fabrication stages in the method of FIG. 1, according to one or more aspects of the present disclosure.

FIGS. 4A, 4B, 4C, 8A, 8B, and 8C illustrate fragmentary top views of an exemplary semiconductor structure during various fabrication stages in the method of FIG. 1, according to one or more aspects of the present disclosure.

FIGS. 9 and 10 illustrate fragmentary cross-sectional views of alternative semiconductor structures according to one or more aspects of the present disclosure.

FIG. 11 illustrates a fragmentary schematic top view of an exemplary semiconductor structure according to one or more aspects of the present disclosure.

FIG. 12 illustrates a fragmentary schematic cross-sectional view of an exemplary semiconductor structure according to one or more aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Through substrate vias (TSVs) are commonly used in three-dimensional integrated circuits (3DICs) because they route electrical signal from one side of a silicon substrate of an IC to the other side thereof. The formation of TSVs may generate stress on surrounding structures, causing delamination and failures. Protective structures (e.g., guard rings) have been developed to reduce, absorb, or isolate the stress generated by TSVs. While existing protective structures are generally adequate for their intended purposes, they are not satisfactory in all aspects.

In addition, as the integrated circuits continue to scale down, so do the power rails. This leads to increased voltage drop across the power rails, as well as increased power consumption of the integrated circuits. One area of interest is forming backside structures, such as power rails and vias on the back side of an IC. Plasma treatment (e.g., plasma etching processes) may be used to form backside power rails and vias and may cause plasma-induced damage (PID) to occur in previously formed devices, thereby causing channel resistance degradation, threshold voltage shift, circuit leakage, failed device yield, and/or reduced device reliability. Therefore, although existing semiconductor structures have been generally adequate for their intended purposes, they have not been entirely satisfactory in all respects.

The present disclosure is generally related to structures including a guard ring structure surrounding one or more TSVs. More specifically, the present disclosure provides a semiconductor structure including a guard ring structure surrounding a region in a top view. The guard ring structure includes frontside conductive features, backside conductive features, and front-end-of-line (FEOL) features and middle-end-of-line (MEOL) features connecting the frontside conductive features and the backside conductive features. The guard ring structure is connected to a discharging structure, such as a diode, a reference voltage, or a diode connected to a reference voltage. The reference voltage may be VSS. The semiconductor structure may further include a through substrate via (TSV) vertically extending in the region surrounded by the guard ring structure. By connecting the guard ring structure to the discharging structure, electrical charges generated during and after manufacturing processes (e.g., backside metal processes) may be discharged promptly, charge accumulation in the guard ring structure is avoided, thus potential risk for guard ring structure damage (e.g., plasma induced damage (PID)) is mitigated. PID to other devices may also be reduced. By having the guard ring structure surrounding the TSV, noise to the TSV may be lowered and performance of the TSV may be improved. Thus, overall performance of the semiconductor structure may be improved.

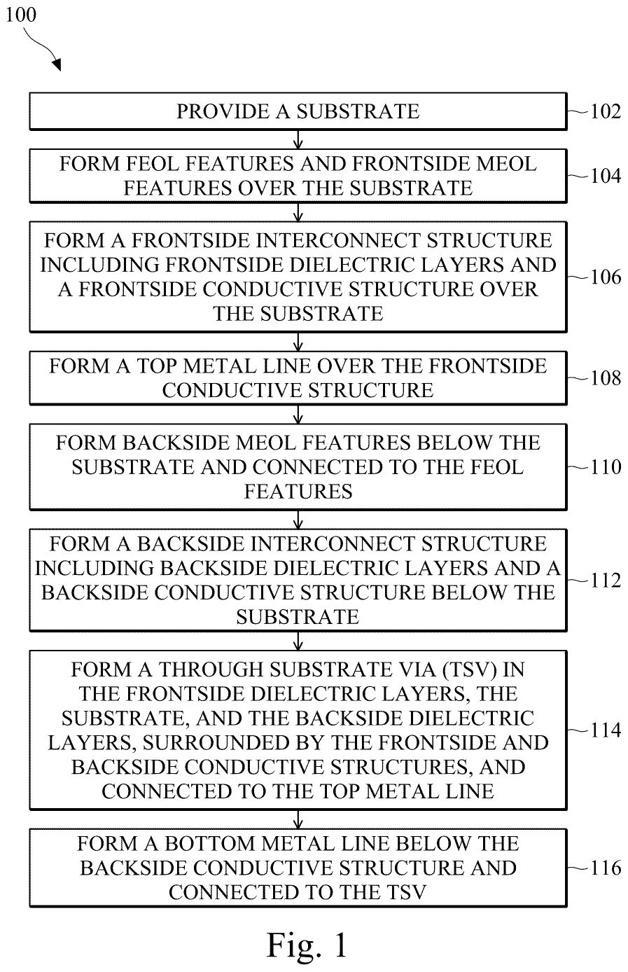

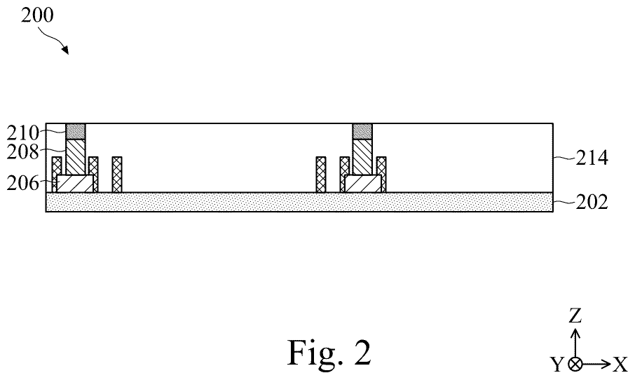

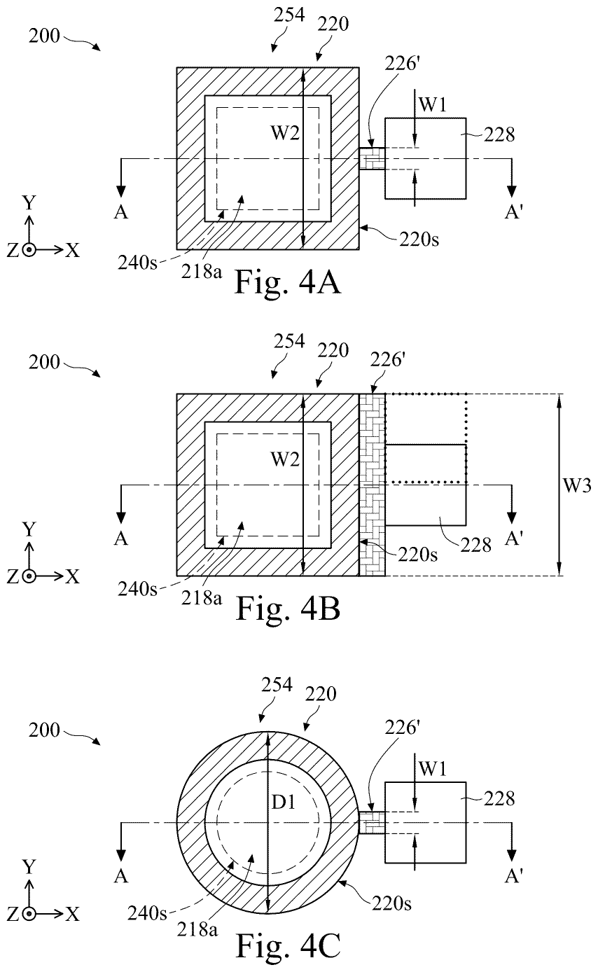

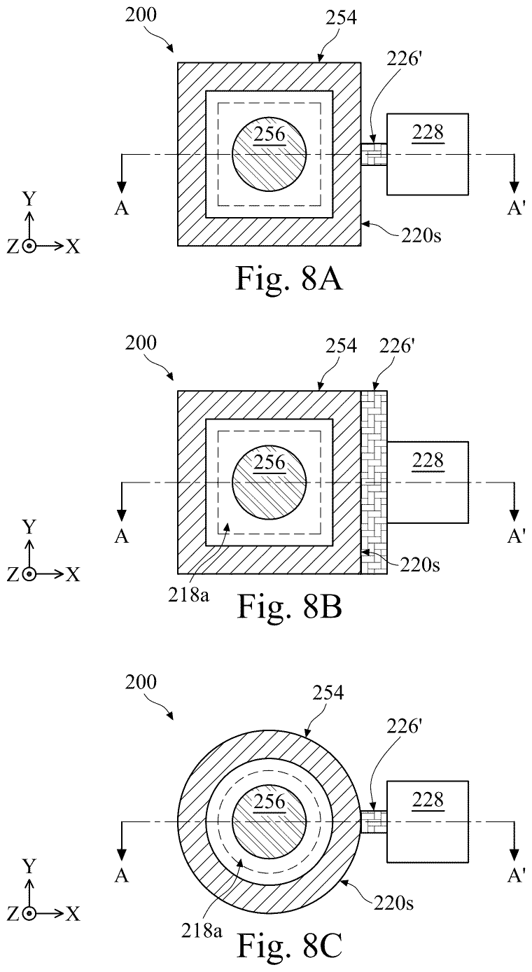

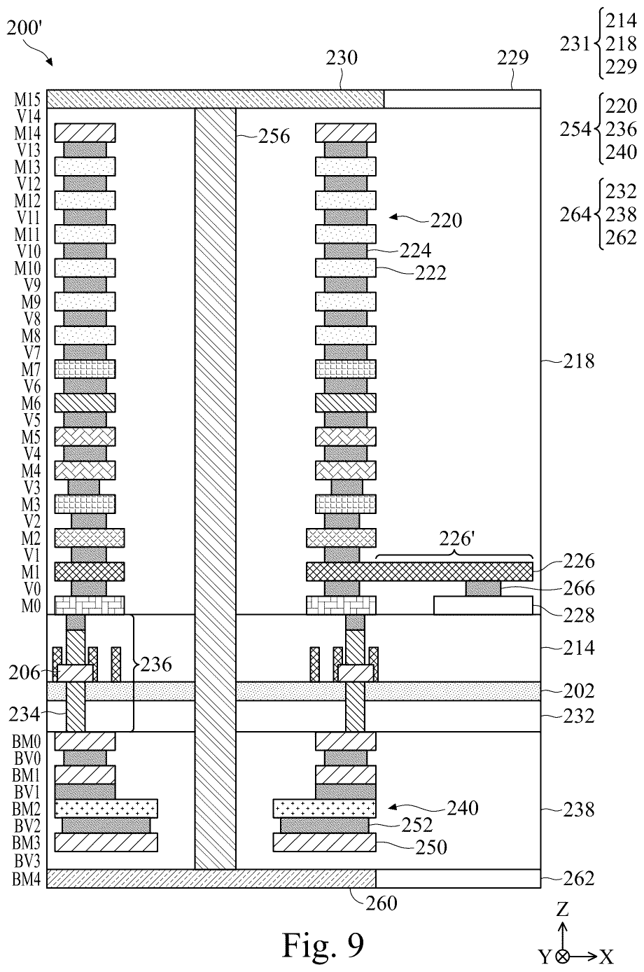

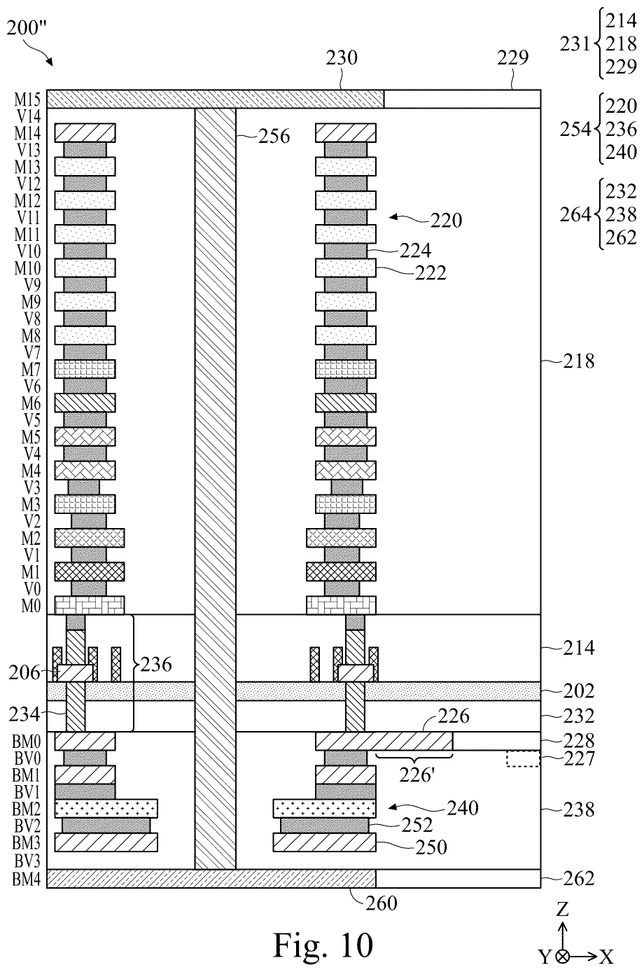

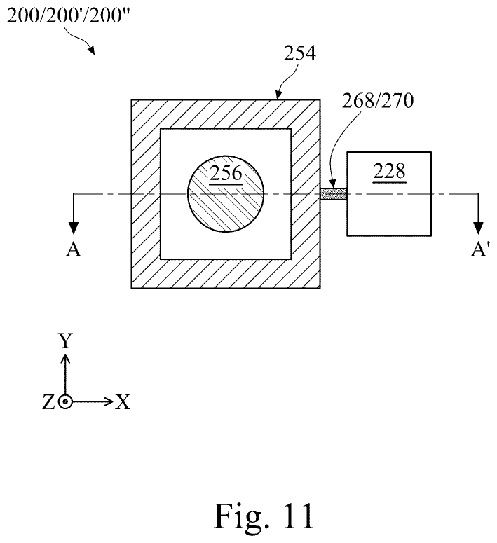

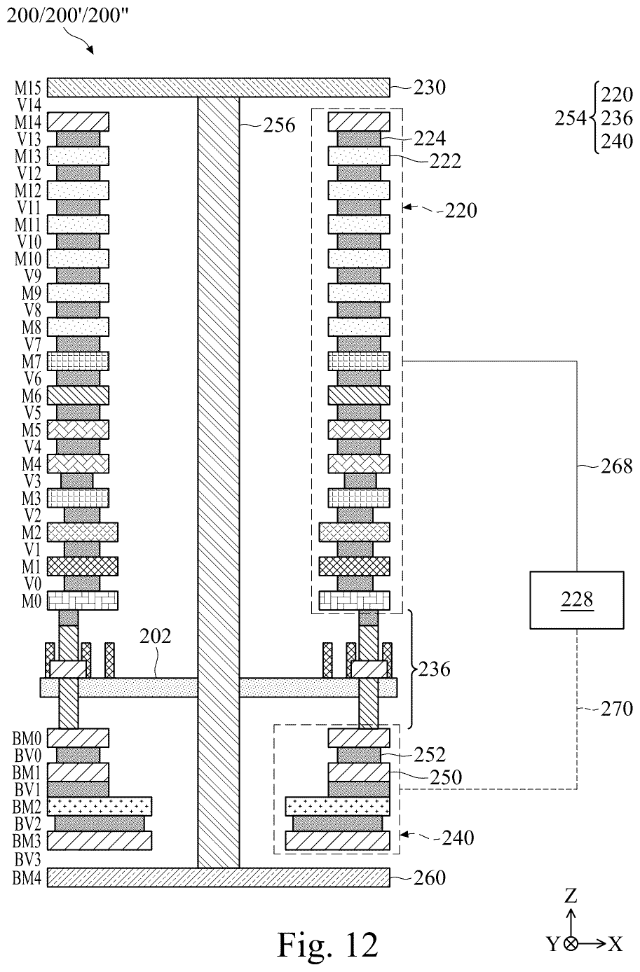

The various aspects of the present disclosure will now be described in more detail with reference to the figures. In that regard, FIG. 1 is a flowchart illustrating method 100 of forming a structure, such as the structure 200 according to embodiments of the present disclosure. Method 100 is described below in conjunction with FIGS. 2-8C. FIGS. 2-3 and 5-7 are fragmentary cross-sectional views of the structure 200 at different stages of fabrication according to embodiments of method 100 in FIG. 1. FIGS. 4A-4C and 8A-8C illustrate fragmentary top views of the structure 200 at different stages of fabrication according to embodiments of method 100 in FIG. 1. FIGS. 9 and 10 illustrate fragmentary cross-sectional views of alternative structures 200′ and 200″, respectively, according to embodiments of the present disclosure. FIGS. 11 and 12 illustrate fragmentary schematic top and cross-sectional views of an exemplary structure 200, respectively, according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of method 100. Not all steps are described herein in detail for reasons of simplicity. Because the structure 200 (or 200′, 200″) will be fabricated into a semiconductor structure or a semiconductor device, the structure 200 (or 200′, 200″) may be referred to herein as a semiconductor structure 200 (or 200′, 200″) or a semiconductor device 200 (or 200′, 200″) as the context requires. For avoidance of doubts, the X, Y and Z directions in FIGS. 2-12 are perpendicular to one another and are used consistently throughout the present disclosure. Throughout the present disclosure, like reference numerals denote like features unless otherwise excepted. That is, material properties and comparisons thereof for various numbered elements described in association with a method or a figure should apply to the same numbered elements described in association with a different method or a different figure.

Further, the semiconductor structures disclosed herein may include various other devices and features, such as other types of devices including transistors, bipolar junction transistors, resistors, capacitors, inductors, diodes, fuses, SRAM and/or other logic circuits, etc., but are simplified for a better understanding of the inventive concepts of the present disclosure. In some embodiments, the exemplary devices include a plurality of semiconductor devices (e.g., transistors), including n-type GAA transistors, p-type GAA transistors, PFETs, NFETs, etc., which may be interconnected.

Referring to FIGS. 1 and 2, method 100 includes a block 102 where a substrate 202 is provided. The substrate 202 is a part of a structure 200, which will include further structures as method 100 progresses. In an embodiment, the substrate 202 includes silicon (Si). Alternatively or additionally, the substrate 202 may include another elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide; an alloy semiconductor, such as silicon germanium (SiGe), GaAsP, AlInAs, AlGaAs, GaInAs, GaInP, and/or GaInAsP; or combinations thereof. Alternatively, the substrate 202 may be a semiconductor-on-insulator substrate, such as a silicon-on-insulator (SOI) substrate, a silicon germanium-on-insulator (SGOI) substrate, or a germanium-on-insulator (GeOI) substrate. Semiconductor-on-insulator substrates can be fabricated using separation by implantation of oxygen (SIMOX), wafer bonding, and/or other suitable methods. The substrate 202 can include various doped regions (not shown) depending on design requirements of device structure 200. In some implementations, the substrate 202 includes p-type doped regions (for example, p-type wells) doped with p-type dopants, such as boron (for example, BF₂), indium, other p-type dopant, or combinations thereof. In some implementations, the substrate 202 includes n-type doped regions (for example, n-type wells) doped with n-type dopants, such as phosphorus (P), arsenic (As), other n-type dopant, or combinations thereof. In some implementations, the substrate 202 includes doped regions formed with a combination of p-type dopants and n-type dopants. The various doped regions can be formed directly on and/or in the substrate 202, for example, providing a p-well structure, an n-well structure, a dual-well structure, a raised structure, or combinations thereof. An ion implantation process, a diffusion process, and/or other suitable doping process can be performed to form the various doped regions.

Still referring to FIGS. 1 and 2, method 100 includes a block 104 where front-end-of-line (FEOL) features and frontside middle-end-of-line (MEOL) features are formed over the substrate 202. FEOL generally encompasses processes related to fabricating IC devices, such as transistors. For example, FEOL processes can include forming FEOL features such as isolation features, gate structures, and source and drain features (generally referred to as source/drain features). MEOL generally encompasses processes related to fabricating MEOL features such as contacts to conductive features (or conductive regions) of the IC devices, such as contacts to the gate structures and/or the source/drain features. In some embodiments, as depicted, the FEOL features include source/drain features 206, and the frontside MEOL features include source/drain contacts 208 and source/drain vias 210.

The FEOL features may include devices, e.g., a planar transistor or a multi-gate transistor, such as a fin-like FET (FinFET) or a gate-all-around (GAA) transistor. A GAA transistor may include channel regions of various shapes including nanowire, nanobar, or nanosheet, which may be collectively referred to as nanostructures. A GAA transistor may also be referred to as a multi-bridge-channel (MBC) transistor or a surrounding-gate-transistor (SGT). The devices may include a FinFET that includes a gate structure wrapping over a channel region of a fin structure arising from the substrate 202 and source/drain features (e.g., source/drain features 206) disposed over source/drain regions of the fin structure. The fin structure may be formed from the substrate 202, which may be a silicon (Si) substrate, or from an epitaxial layer formed on the substrate 202. In the latter case, the epitaxial layer may include germanium (Ge) or silicon germanium (SiGe).

While not explicitly shown, the gate structure includes an interfacial layer interfacing the fin structure, a gate dielectric layer over the interfacial layer, and a gate electrode layer over the gate dielectric layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The gate dielectric layer may be formed by ALD, physical vapor deposition (PVD), CVD, oxidation, and/or other suitable methods.

The gate electrode layer of the gate structure may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof.

The source/drain features 206 may be deposited using vapor-phase epitaxy (VPE), ultra-high vacuum CVD (UHV-CVD), molecular beam epitaxy (MBE), and/or other suitable processes. When the source/drain feature 206 is n-type, it may include silicon (Si) doped with an n-type dopant, such as phosphorus (P) or arsenic (As). When the source/drain feature 206 is p-type, it may include silicon germanium (SiGe) doped with a p-type dopant, such as boron (B) or boron difluoride (BF₂). In some alternative embodiments not explicitly shown in the figures, the source/drain feature 206 may include multiple layers, such as a lightly doped first epitaxial layer over source/drain region of the fin structure, a heavily doped second epitaxial layer over the lightly doped first epitaxial layer, and a capping epitaxial layer disposed over the heavily doped second epitaxial layer.

Although not explicitly shown in FIG. 2, multiple active regions (e.g., fin structures) are formed over the substrate 202. The active regions may be isolated from one another by an isolation feature. In some implementations, the isolation features may be formed by etching a trench in substrate 202 or an epitaxial layer on the substrate using a dry etch process and filling the trench with insulator material using a chemical vapor deposition (CVD) process, flowable CVD (FCVD) process, or a spin-on glass process. A chemical mechanical polishing (CMP) process may be performed to remove excessive insulator material and to provide a planar surface. The insulator material is then etched back to form the isolation feature such that the active regions rise above the isolation feature. In some implementations, the isolation features may include a multi-layer structure that includes a liner dielectric layer and bulk dielectric layer. The isolation feature may include silicon oxide, silicon oxynitride, boron silicate glass (BSG), or phosphosilicate glass (PSG).

The operations at block 104 may include forming an interlayer dielectric (ILD) layer 214 over the substrate 202. In the depicted embodiment, the frontside MEOL features are disposed in the ILD layer 214. As shown in FIG. 2, the source/drain contact 208 extends in the ILD layer 214 to be physically and electrically connected to one of the source/drain features 206. In some embodiments, the ILD layer 214 may include silicon oxide, tetraethylorthosilicate (TEOS) oxide, un-doped silicate glass (USG), or doped silicon oxide such as borophosphosilicate glass (BPSG), fused silicate glass (FSG), phosphosilicate glass (PSG), boron doped silicate glass (BSG), and/or other suitable dielectric materials. ILD layer 214 may include multiple layers. The ILD layer 214 may be deposited using PECVD, FCVD, spin-on coating, or a suitable deposition technique. In some embodiments, after formation of the ILD layer 214, the structure 200 may be annealed to improve integrity of the ILD layer 214. The source/drain contacts 208 may include ruthenium (Ru), cobalt (Co), nickel (Ni), or copper (Cu). The source/drain contacts 208 may be deposited using CVD, PVD, or a suitable method. Although not shown in figures, a contact etch stop layer (CESL) may be deposited before the ILD layer 214 is deposited such that the CESL is disposed between the ILD layer 214 and the source/drain features 206. The CESL may include silicon nitride or silicon oxynitride and may be deposited using CVD, ALD, or a suitable method. In some embodiments not explicitly shown, the source/drain contact 208 may include a barrier layer to interface the ILD layer 214. Such a barrier layer may include a metal nitride, such as titanium nitride, tantalum nitride, tungsten nitride, cobalt nitride, or nickel nitride. Additionally, in order to reduce contact resistance, a silicide feature may be disposed between the source/drain contact 208 and the source/drain feature 206. The silicide feature may include titanium silicide. The source/drain via 210 extends in the ILD layer 214 to be physically and electrically connected to the source/drain contact 208. The source/drain via 210 may include conductive materials, such as Cu, aluminum (Al), Co, Ru, or Ni.

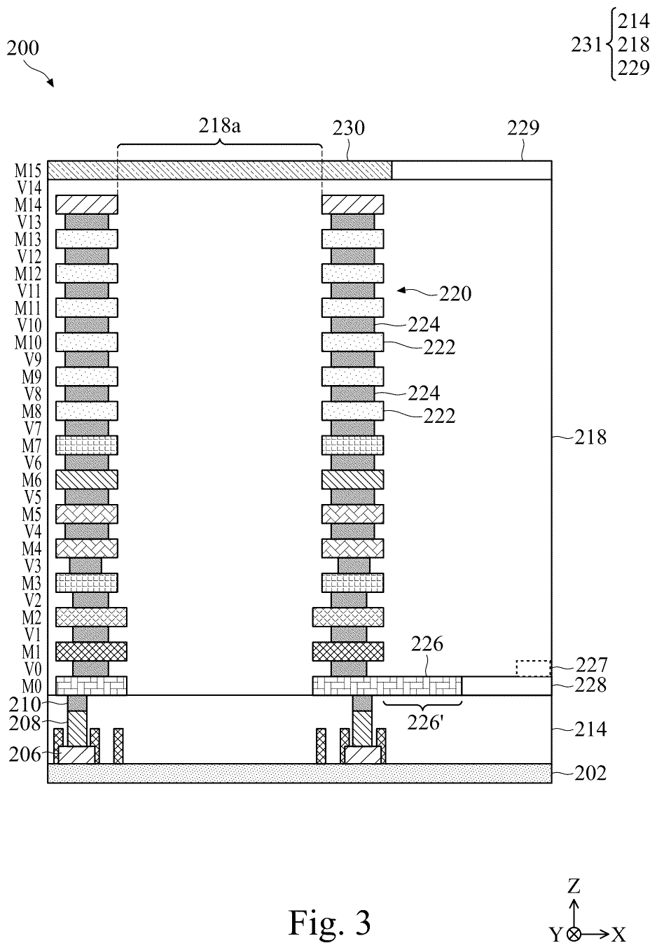

Referring to FIGS. 1 and 3-4C, method 100 includes a block 106 where a frontside interconnect structure is formed over the substrate 202 and the ILD layer 214. The frontside interconnect structure includes a frontside dielectric structure 218 and a frontside conductive structure 220. FIG. 3 illustrates a fragmentary cross-sectional view of the structure 200 taken along line A-A′ as in FIG. 4A, which illustrates a fragmentary top view of the structure 200. FIGS. 4B and 4C illustrate alternative fragmentary top views of the structure 200 according to various embodiments of the present disclosure.

Referring to FIG. 3, although not explicitly shown, the frontside dielectric structure 218 may include a plurality of dielectric layers (e.g., intermetal dielectric (IMD) layers and an etch stop layers (ESLs)). It can be said that ESLs interleave the IMD layers or that the IMD layers interleave the ESLs. The ESLs may share the same composition and may include silicon nitride or silicon oxynitride. The IMD layers may share the same composition and may include silicon oxide, tetraethylorthosilicate (TEOS) oxide, un-doped silicate glass (USG), or doped silicon oxide such as borophosphosilicate glass (BPSG), fused silicate glass (FSG), phosphosilicate glass (PSG), boron doped silicate glass (BSG), low-k dielectric material, other suitable dielectric material, or combinations thereof. Example low-k dielectric materials include carbon doped silicon oxide, Xerogel, Aerogel, amorphous fluorinated carbon, benzocyclobutene (BCB), or polyimide.

The frontside conductive structure 220 may be disposed in the frontside dielectric structure 218. The frontside conductive structure 220 may include a plurality of conductive features (e.g., metal lines, metal vias). In some embodiments, the frontside conductive structure 220 includes metal lines 222 and vias 224 as depicted in FIG. 3. The conductive features may each extend continuously around a space to form a closed loop in a top view. In other words, the conductive features may each form a ring in the top view. Thus, the conductive features may be referred to as ring layers. As shown in FIG. 4A, the frontside conductive structure 220 is a closed loop along an X-Y plane such that a portion of the frontside dielectric structure 218 is enclosed by the frontside conductive structure 220. The frontside conductive structure 220 may have any suitable shape in a top view, such as square (as in FIGS. 4A and 4B), circle (e.g., as in FIG. 4C), rectangle, oval, triangle, hexagonal, octagonal, or other polygonal shape. The frontside conductive structure 220 may completely surround a portion 218a of the frontside dielectric structure 218, such that the portion 218a of the frontside dielectric structure 218 in the frontside conductive structure 220 is isolated from the rest of the frontside dielectric structure 218 by the frontside conductive structure 220.

In the depicted embodiment of FIG. 3, the frontside interconnect structure includes a metal zero interconnect layer (M0 level), a via zero interconnect layer (V0 level), a metal one interconnect layer (M1 level), a via one interconnect layer (V1 level), . . . a metal thirteen interconnect layer (M13 level), a via thirteen interconnect layer (V13 level), and a metal fourteen interconnect layer (M14 level). Each of the M0 level, V0 level, M1 level, V1 level, . . . M13 level, V13 level, and M14 level may be referred to as a metal level. Metal lines formed at the M0 level may be referred to as M0 metal lines. Similarly, via or metal lines formed at the V0 level, M1 level, V1 level, M2 level, . . . V13 level, and M14 level may be referred to as V0 vias, M1 metal lines, V1 vias, M2 metal lines, . . . V13 vias, and M14 metal lines, respectively. The present disclosure contemplates frontside interconnect structure having more or less interconnect layers (including metal line interconnect layers and via interconnect layers) and/or levels, for example, a total number of N interconnect layers of the frontside interconnect structure with N as an integer ranging from 1 to 40. Each level of the frontside interconnect structure includes conductive features (e.g., metal lines 222, metal vias 224) disposed in one or more dielectric layers (e.g., an IMD layer and an ESL) of the frontside dielectric structure 218. In some embodiments, the frontside dielectric structure 218 includes one or more dielectric layers (e.g., corresponding to V14 level as depicted) above the frontside conductive structure 220. The conductive features may each form a closed loop along an X-Y plane. The conductive features may have substantially the same shape (e.g., the shape of the frontside conductive structure 220 described above) from a top view along the Z direction. The conductive features may overlap from the top view as in FIGS. 3-4C.

In the depicted embodiment, the source/drain vias 210 connect the source/drain contacts 208 to M0 metal lines. In some embodiments, the source/drain vias 210 may also include butted contacts. M0 level includes M0 metal lines disposed in the frontside dielectric structure 218. V0 level includes V0 vias disposed in the frontside dielectric structure 218, where V0 vias connect M0 metal lines to M1 metal lines. Similarly, Mx level includes Mx metal lines disposed in the frontside dielectric structure 218. Vx level includes Vx vias disposed in the frontside dielectric structure 218, where Vx vias connect Mx metal lines to M(x+1) metal lines. M(x+1) level includes M(x+1) metal lines disposed in the frontside dielectric structure 218. x is an integer. In the depicted embodiment, x may be from 0 to 13.

At block 106, the frontside interconnect structure may be formed layer by layer from bottom to top. In some embodiments, the conductive features at a same level of the frontside conductive structure 220, such as M0 level, are formed simultaneously. In some embodiments, conductive features at a same level of the frontside conductive structure 220 have top surfaces that are substantially planar with one another and/or bottom surfaces that are substantially planar with one another.

Forming the conductive feature (e.g., the metal line 222, the via 224) at a level may include depositing dielectric layer(s) (e.g., an IMD layer and an ESL) of the frontside dielectric structure 218 at the level, patterning/etching the dielectric layer(s) to form an opening, and forming the conductive feature in the opening (e.g., by a damascene process). After forming the conductive feature, the same process steps may be repeated to form another metal layer until the set number of metal layers is reached.

The dielectric layer(s) at the level may be deposited using ALD, CVD, FCVD, spin-on coating, or a suitable deposition method. Patterning the dielectric layer(s) at the level may involve multiple processes such as lithography, etching, and/or cleaning. For example, at least one hard mask is deposited over the dielectric layer(s) at the level using CVD or a suitable process. A photoresist layer is then deposited over the at least one hard mask layer using spin-on coating. The deposited photoresist layer may undergo a pre-exposure baking process, exposure to radiation reflected from or transmitted through a photomask, a post-exposure baking process, and developing process, so as to form a patterned photoresist. The at least one hard mask layer is then etched using the patterned photoresist as an etch mask to form a patterned hard mask. The patterned hard mask is then applied as an etch mask to etch the dielectric layer(s) at the level. The etching of the dielectric layer(s) at the level may include a dry etch process (e.g., a plasma etching process), a wet etch process, or a combination thereof. In some instances, different etch processes or different etchant chemistries may be used to etch the dielectric layer(s) at the level. After the dielectric layer(s) at the level are patterned, the residual patterned photoresist may be removed by ashing, stripping, or selective etching.

After the opening is formed in the dielectric layer(s) at the level, the conductive feature at the level may be formed using a damascene process (e.g., single damascene or dual damascene processes). The conductive features (e.g., the vias 224 and the metal lines 222) in the frontside conductive structure 220 may include titanium (Ti), ruthenium (Ru), nickel (Ni), cobalt (Co), copper (Cu), molybdenum (Mo), tungsten (W), aluminum (Al), and/or other suitable materials. In one embodiment, they may include copper (Cu). In some embodiments, in order to prevent electromigration from the metal material or oxygen diffusion from the frontside dielectric structure 218 into the metal material, the vias 224 and the metal lines 222 may each include a barrier layer to interface the frontside dielectric structure 218. The barrier layer may include titanium nitride (TiN), tantalum nitride (TaN), or cobalt nitride (CoN). In an example process to fill the opening in the dielectric layer(s) at the level, a barrier layer is first deposited over the opening using ALD, PVD, CVD, metal organic CVD (MOCVD), or a suitable method. A seed layer is then deposited over the barrier layer using ALD, PVD, CVD, MOCVD, or a suitable method. In some instances, the seed layer may include titanium or copper. Then a bulk metal layer may be deposited on the seed layer using electroplating or electroless plating. In one embodiment, the bulk metal layer may include copper. In some alternative embodiments, the seed layer may be omitted and the openings are filled with titanium (Ti), ruthenium (Ru), nickel (Ni), cobalt (Co), copper (Cu), molybdenum (Mo), tungsten (W), aluminum (Al) using PVD, CVD, MOCVD, or a suitable method, After the filling with the barrier layer, the seed layer, and the bulk metal layer, the structure 200 is planarized using, for example CMP, to form the conductive feature at the level.

In some embodiments, one of the metal lines 222 and the metal vias 224 is formed as an extended metal line 226. The extended metal line 226 has a width greater than the other metal lines 222 and vias 224 along the X-direction. In the depicted embodiment, M0 metal line is formed as the extended metal line 226. Except the extended metal line 226, a lower-level metal line (e.g., M1 metal line) of the frontside conductive structure 220 may have a width greater than a width of a higher-level metal line at (e.g., M13 metal line) along the X-direction.

Referring to FIGS. 4A to 4C, the extended metal line 226 includes an extended portion 226′ extending beyond an outer sidewall 220s of the frontside conductive structure 220 from the top view. Referring to FIG. 4A, the extended portion 226′ may have a width W1 less than a width W2 of the frontside conductive structure 220. W1 and W2 are along the Y-direction. Referring to FIG. 4B, the extended portion 226′ may have a width W3 along the Y-direction same as W2. Referring to FIG. 4C, in some embodiments, the frontside conductive structure 220 has a circular shape, and the extended portion 226′ may have a width W1 less than a diameter D1 of the circle.

Forming the frontside conductive structure 220 may include processes (e.g., a plasma etching process) that generate electrical charges. The charges may be discharged through a discharging structure 228 (to be described) electrically connected to the extended metal line 226 and/or through the substrate 202, with the substrate 202 being grounded at this stage. In some embodiments, the substrate 202 is not grounded, and the charges are discharged through the discharging structure 228. Thus, charge accumulation in the frontside conductive structure is avoided and/or reduced.

In some embodiments, operations at block 106 include forming the discharging structure 228 connected to the extended metal line 226. The discharging structure 228 may include a diode or a conductive feature (e.g., a conductive line) connected to a first reference voltage.

The conductive line connected to the first reference voltage may be disposed in a same metal level as the extended metal line 226 as depicted. The conductive line may be connected to the first reference voltage by other conductive feature(s) (e.g., a conductive via 227) in adjacent metal level(s). The conductive feature(s) (e.g., the conductive via 227) may be above or below the conductive line. The via 227 is depicted in a dashed rectangle, because in some embodiments (e.g., when the discharging structure 228 includes a diode), the via 227 may be omitted. The conductive line connected to the first reference voltage may have similar materials and be formed using similar methods as the conductive features of the frontside conductive structure 220. The extended metal line 226 and the conductive line connected to the first reference voltage may be formed simultaneously or separately. When the extended metal line 226 and the conductive line connected to the first reference voltage are formed simultaneously, they may merge as one continuous metal line. In such embodiments, the operations at block 106 may include forming an opening for both the extended metal line 226 and the conductive line connected to the first reference voltage, and forming the barrier layer, optionally a seed layer, and a bulk metal layer in the opening. In some embodiments, the first reference voltage is VSS (i.e., ground or negative supply voltage). In such embodiments, the conductive line is also referred to as a VSS conductive line. The via 227 may be formed similarly as V0 vias.

In some embodiments, the discharging structure 228 includes the diode. The diode may include a p-n junction. Forming the diode may use any suitable method. In an example process, forming the diode includes forming a diode opening in the dielectric layer(s) of the frontside dielectric structure 218 at the level, depositing semiconductor materials (e.g., silicon, germanium, polysilicon, amorphous silicon) in the diode opening, doping a first portion of the semiconductor materials with a p-type dopant (such as boron (B) or boron difluoride (BF₂)), and doping a second portion of the semiconductor materials with an n-type dopant (such as phosphorus (P) or arsenic (As)). In some embodiments, the first portion and the second portion are in direct contact. In some other embodiments, the diode further includes an undoped semiconductor component (e.g., a third portion of the semiconductor materials) between the first portion and the second portion. The undoped semiconductor component is also referred to as an intrinsic component. In some embodiments, the diode is electrically connected to a second reference voltage by the via 227. The second reference voltage may be VSS (i.e., ground or negative supply voltage).

It is noted that the dimension, the shape, and the position of the discharging structure 228 in FIGS. 3-4C are for illustration purpose only. The discharging structure 228 may have any suitable dimensions and/or suitable shapes from the top view, such as square, circle, rectangle, oval, triangle, hexagonal, octagonal, or other polygonal shape. The discharging structure 228 may be in any suitable position, such as in the dotted square in FIG. 4B, as long as the discharging structure 228 is connected to the extended portion 226′.

Still referring to FIGS. 1 and 3-4C, method 100 includes a block 108 where a top metal line 230 is formed above the frontside conductive structure 220. In some embodiments, the top metal line 230 may not be a closed loop in a top view. The top metal line 230 may include similar materials and be formed using similar method as the metal lines 222 described above. Forming the top metal line 230 may include forming additional dielectric layers 229 (e.g., an IMD layer and an ESL) over the frontside dielectric structure 218. The top metal line 230 is isolated from the frontside conductive structure 220 by a portion of the frontside dielectric structure 218. The ILD layer 214, the frontside dielectric structure 218, and the additional dielectric layers 229 may be collectively referred to as a combined frontside dielectric structure 231.

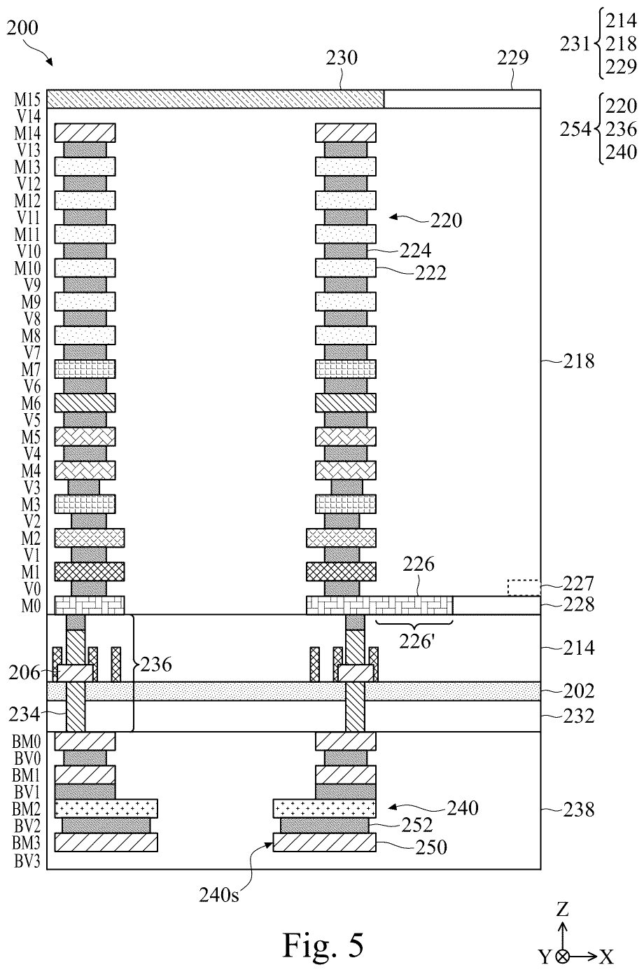

Referring to FIGS. 1 and 5, method 100 includes a block 110 where backside MEOL features and a backside dielectric layer 232 are formed below the substrate 202. The FEOL features, the frontside MEOL features, and the backside MEOL features may collectively be referred to as a device layer structure 236. The frontside MEOL features and the backside MEOL features may collectively be referred to as MEOL features. The backside MEOL features are electrically connected to the FEOL features. The backside MEOL features may extend through the substrate 202 and the backside dielectric layer 232. In the depicted embodiment, the backside MEOL features include backside contacts 234. The backside contact 234 extends in the backside dielectric layer 232 to be electrically connected to one of the source/drain features 206.

The backside dielectric layer 232 may include similar materials and be formed using similar methods as the ILD layer 214. Before forming the backside dielectric layer 232, a CESL may be formed below the substrate 202. The backside contacts 234 may include similar materials and be formed using similar methods as the source/drain contacts 208 described above. A backside silicide feature similar to the silicide feature described above may be disposed between the backside contact 234 and the source/drain feature 206.

Still referring to FIGS. 1 and 5, method 100 includes a block 112 where a backside interconnect structure is formed below the substrate 202 and the backside dielectric layer 232. The backside interconnect structure includes a backside dielectric structure 238 and a backside conductive structure 240. The frontside conductive structure 220, the device layer structure 236, and the backside conductive structure 240 collectively form a guard ring structure 254. The backside conductive structure 240 is connected to the FEOL features by the backside MEOL features.

The backside dielectric structure 238 may include a plurality of dielectric layers (e.g., IMD layers and ESLs) similar to the frontside dielectric structure 218. The backside conductive structure 240 may be disposed in the backside dielectric structure 238. The backside conductive structure 240 may include backside conductive features (e.g., backside metal lines, backside metal vias) similar to the conductive features of the frontside conductive structure 220. In some embodiments, the backside conductive structure 240 includes backside metal lines 250 and backside vias 252 as depicted in FIG. 5. The backside metal lines 250 and backside vias 252 may include similar structures (e.g., the barrier layer, the seed layer, and the bulk metal layer), materials, and shapes from a top view as the metal lines 222 and vias 224 and may be formed using similar methods as the metal lines 222 and vias 224.

In the depicted embodiment of FIG. 5, the backside interconnect structure includes a backside metal zero interconnect layer (BM0 level), a backside via zero interconnect layer (BV0 level), a backside metal one interconnect layer (BM1 level), a backside via one interconnect layer (BV1 level), a backside metal two interconnect layer (BM2 level), a backside via two interconnect layer (BV2 level), and a backside metal three interconnect layer (BM3 level). Each of the BM0 level, BV0 level, BM1 level, BV1 level, BM2 level, BV2 level, and BM3 level may be referred to as a metal level. Metal lines formed at the BM0 level may be referred to as BM0 metal lines. Similarly, via or metal lines formed at the BV0 level, BM1 level, BV1 level, BM2 level, BV2 level, and BM3 level may be referred to as BV0 vias, BM1 metal lines, BV1 vias, BM2 metal lines, BV2 vias, and BM3 metal lines, respectively. The present disclosure contemplates backside interconnect structure having more or less interconnect layers (including metal line interconnect layers and via interconnect layers) and/or levels, for example, a total number of Q interconnect layers (levels) of the backside interconnect structure with Q as an integer ranging from 1 to 40. Each level of the backside interconnect structure includes backside conductive features (e.g., backside metal lines, backside metal vias) disposed in one or more dielectric layers (e.g., an IMD layer and an ESL) of the backside dielectric structure 238. In some embodiments, the backside dielectric structure 238 include one or more dielectric layers (e.g., corresponding to BV3 level as depicted) below the backside conductive structure 240.

In the depicted embodiment, the backside contacts 234 connect the source/drain features 206 to BM0 metal lines. BM0 level includes BM0 metal lines disposed in the backside dielectric structure 238. The BV0 level includes BV0 vias disposed in the backside dielectric structure 238, where BV0 vias connect BM0 metal lines to BM1 metal lines. Similarly, BMy level includes BMy metal lines disposed in the backside dielectric structure 238. BVy level includes BVy vias disposed in the backside dielectric structure 238, where BVy vias connect BMy metal lines to BM(y+1) metal lines. BM(y+1) level includes BM(y+1) metal lines disposed in the backside dielectric structure 238. y is an integer. In the depicted embodiment, y may be from 0 to 2.

The backside conductive features may each form a closed loop along an X-Y plane. The backside conductive features may have substantially the same shape (e.g., the shape of the frontside conductive structure 220 described above) from a top view along the Z direction. The backside conductive features may overlap from the top view. FIGS. 4A-4C may represent fragmentary top views of the structure 200 at block 112 according to various embodiments of the present disclosure.

Referring to FIG. 5, a lower-level (e.g., BM3 level) metal line of the backside conductive structure 240 may have a width greater than a width of a higher-level (e.g., BM0 level) metal line along the X-direction. A lower-level (e.g., BV2 level) via of the backside conductive structure 240 may have a width greater than a width of a higher-level (e.g., BV0 level) via along the X-direction. The bottommost metal line and the bottommost via of the backside conductive structure 240 may have widths along a horizontal direction (e.g., the X-direction or the Y-direction) greater than those of metal lines 222 and vias 224 (except the extended metal line 226) of the frontside conductive structure 220, respectively. The widths differences described above may apply to radical widths in the embodiments where the guard ring structure 254 has a circular shape. The dashed squares in FIGS. 4A and 4B and the dashed circle in FIG. 4C represent inner sidewalls 240s of the backside conductive structure 240. Wider widths in the lower-level conductive features (or backside conductive features) may provide more mechanical support to the structures (e.g., the conductive features and/or the backside conductive features) thereabove, thus improving integrity of the guard ring structure 254. In the depicted embodiment, outer sidewalls of the metal lines of the backside conductive structure 240 and the frontside conductive structure 220 substantially align. Thus, the width W2 and the diameter D1 in FIGS. 4A-4C are also the width and the diameter of the guard ring structure 254, respectively.

Referring to FIGS. 4A-4C, in some embodiments, the guard ring structure 254 has a ring pattern between the outer sidewalls 220s and the inner sidewalls 240s in a top view. The extended portion 226′ laterally extends beyond the outer sidewalls 220s to connect to the discharging structure 228. In the depicted embodiment, the discharging structure 228 is outside and spaced apart from the outer sidewalls 220s.

Forming the backside interconnect structure may use similar method as forming the frontside interconnect structure as described above. At block 112, as compared to operations at block 106, differences include the follows. The backside interconnect structure is formed layer by layer from top to bottom. In some embodiments, the operations (e.g., depositing, patterning, etching) at block 112 may be performed from a back side of the structure 200. The structure 200 may be flipped over for access to its back side. Forming the backside conductive feature (e.g., the metal line 250, the via 252) at a level may include depositing dielectric layer(s) (e.g., an IMD layer and an ESL) of the backside dielectric structure 238 at the level, patterning/etching the dielectric layer(s) to form an opening, and forming the backside conductive feature in the opening (e.g., by a single damascene or a dual damascene process). After forming the backside conductive feature, the same process steps may be repeated to form another metal layer until the set number of metal layers is reached.

Forming the backside conductive structure 240 and the backside contacts 234 may include processes (e.g., a plasma etching process) that generate electrical charges. At these stages, the substrate 202 may not be grounded. The charges may be discharged through the device layer structure 236, the frontside conductive structure 220 including the extended metal line 226, and the discharging structure 228. Thus, charge accumulation in the guard ring structure 254 is avoided and/or reduced. This may reduce potential risk for damages (e.g., PID) to the guard ring structure 254, and may protect other devices (e.g., a device on the substrate 202 and adjacent to the device layer structure 236) in the structure 200 from PID.

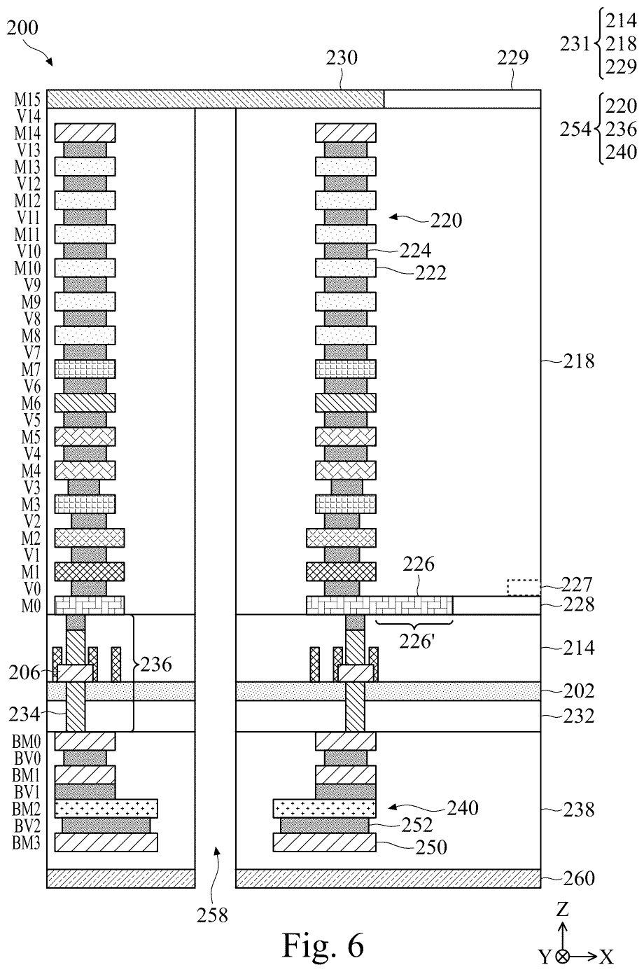

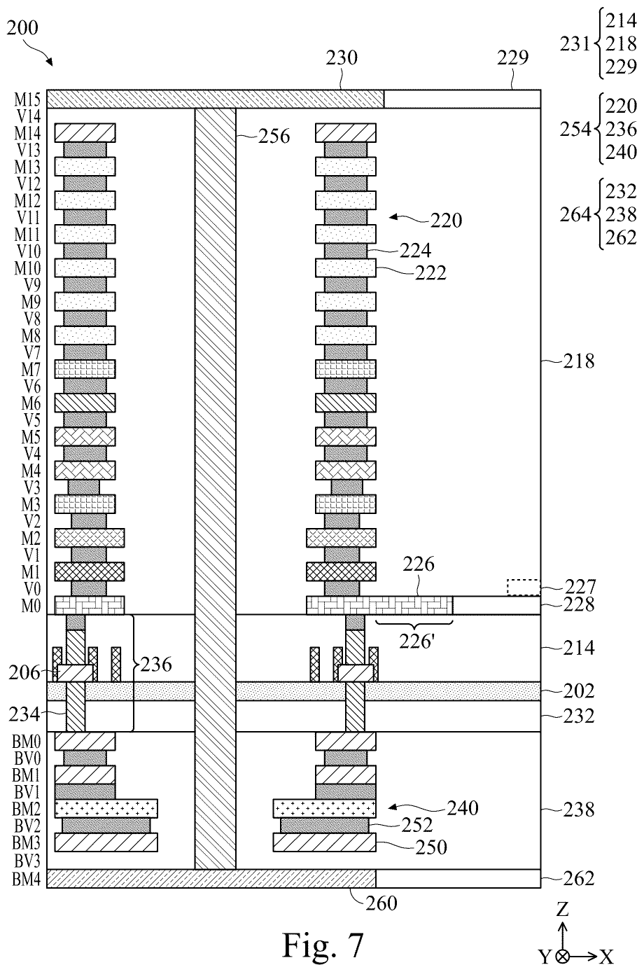

Referring to FIGS. 1 and 6-8C, method 100 includes a block 114 where a through substrate via (TSV) 256 is formed. FIG. 7 illustrates a fragmentary cross-sectional view of the structure 200 as in FIG. 8A, which illustrates a fragmentary top view of the structure 200. FIGS. 8B and 8C illustrate alternative fragmentary top views of the structure 200. FIGS. 8A-8C represent resulted structures fabricated from structures represented by FIGS. 4A-4C, respectively. Operations at block 114 may include forming a TSV trench 258 (shown in FIG. 6) and filling the TSV trench 258 with the TSV 256 (shown in FIGS. 7-8C).

Referring to FIG. 6, A TSV trench 258 may be formed in the frontside dielectric structure 218, the backside dielectric structure 238, the substrate 202, the ILD layer 214, and the backside dielectric layer 232. In some embodiments, forming the TSV trench 258 includes forming a patterned mask layer 260 having an opening therein that exposes a region of the backside dielectric structure 238 surrounded by the guard ring structure 254 and etching the backside dielectric structure 238 and subsequently the backside dielectric layer 232, the substrate 202, the ILD layer 214, and the frontside dielectric structure 218 using the patterned mask layer 260 as an etch mask. The patterned mask layer 260 may be formed using a lithography process, which can include resist coating (for example, spin-on coating), soft baking, mask aligning, exposure, post-exposure baking, developing the resist, rinsing, drying (for example, hard baking), other suitable process, or combinations thereof. In some embodiments, the patterned mask layer 260 is a patterned hard mask layer (e.g., a silicon nitride layer). In some embodiments, the patterned mask layer 260 is a patterned resist layer. The etching may be a dry etching process, a wet etching process, other etching process, or combinations thereof. In some embodiments, the etching process is an isotropic dry etch. In some embodiments, a Bosch process is implemented to extend the TSV trench 258 through the backside dielectric structure 238, the backside dielectric layer 232, the substrate 202, the ILD layer 214, and the frontside dielectric structure 218. A Bosch process generally refers to a high-aspect ratio plasma etching process that involves alternating etch phases and deposition phases, where a cycle includes an etch phase and a deposition phase and the cycle is repeated until the top metal line 230 is exposed.

Referring to FIGS. 7-8C, fabrication proceeds with filling the TSV trench 258 with the TSV 256. The TSV 256 may include a conductive plug, and a barrier layer and a liner disposed on a top surface and sidewalls of the conductive plug. In some embodiments, the TSV 256 is formed by depositing a liner (e.g., silicon oxide, silicon nitride) and a barrier material (e.g., TiN or TaN) on top surface and sidewalls of the TSV trench 258 (so that the liner and the barrier material partially fill the TSV trench 258), depositing a bulk conductive material (e.g., Cu) to fill a remainder of the TSV trench 258, and performing a planarization process (e.g., CMP) to remove excess barrier material and excess bulk conductive material from the structure 200.

The TSV 256 extends through the frontside dielectric structure 218, the substrate 202, the backside dielectric structure 238, the ILD layer 214, and the backside dielectric layer 232. The TSV 256 may be surrounded by the guard ring structure 254, such as depicted in FIGS. 8A-8C. In some embodiments, more than one TSV 256 are formed and surrounded by the guard ring structure 254. The TSV 256 may be physically and electrically connected to the top metal line 230.

The guard ring structure 254 may provide structural barriers surrounding the TSV 256 to prevent moisture from attacking metal materials in the TSV 256. Further, the guard ring structure 254 may provide electrical barriers to isolate electrical interference between nearby components and the TSV 256. Because charge accumulation in the guard ring structure 240 is mitigated, noise to the TSV 256 may be reduced or avoided. Therefore, performance of the TSV structure 256 may be improved, and the overall performance of the structure 200 may be improved.

Still referring to FIGS. 1 and 7-8C, method 100 includes a block 116 where a bottom metal line 260 is formed. The bottom metal line 260 may be physically and electrically connected to the TSV 256. In some embodiments, the bottom metal line 260 may not be a closed loop in a top view. The bottom metal line 260 may include similar materials and be formed using similar method as the top metal line 230 described above. Forming the bottom metal line 260 may include forming additional backside dielectric layers 262 (e.g., an IMD layer and an ESL) below the TSV 256 and the backside dielectric structure 238. The backside dielectric layer 232, the backside dielectric structure 238, and the additional backside dielectric layers 262 may be collectively referred to as a combined backside dielectric structure 264. The bottom metal line 260 is isolated from the guard ring structure 254 by a portion of the backside dielectric structure 238. The semiconductor structure 200 may undergo further processing to form various features and regions known in the art. For example, the semiconductor structure 200 may be packaged as a component of a 3DIC.

Referring to FIG. 9, a fragmentary cross-sectional view of an alternative structure 200′ made by method 100 is provided. Differences from the structure 200 described above are as follows. As depicted, the extended metal line 226 of the structure 200′ is an M1 metal line. The extended metal line 226 may be connected to the discharging structure 228 by a V0 via 266. The V0 via 266 may be formed simultaneously and using similar method as the other V0 vias. In such embodiments, the extended metal line 226 overlaps with the discharging structure 228 in a top view. In some embodiments, the discharging structure 228 is further connected to a via (e.g., a V0 via other than the V0 via 266). The via may be connected to a VSS voltage.

Referring to FIG. 10, a fragmentary cross-sectional view of an alternative structure 200″ made by method 100 is provided. Differences from the structure 200 described above are as follows. As depicted, the extended metal line 226 of the structure 200″ is a BM0 metal line, and the discharging structure 228 may be disposed in the BM0 level. The extended metal line 226 may be in contact with the discharging structure 228 directly. The conductive via 227 is below the discharging structure 228 in the depicted embodiment. The extended metal line 226 and the discharging structure 228 may be formed in operations at block 112. The discharging structure 228 of the structure 200″ may be formed similarly to the discharging structure 228 of the structure 200 as described above, except for the position difference.

FIG. 11 illustrates a schematic fragmentary top view of the structure 200 or an alternative structure (e.g., 200′, 200″). FIG. 12 illustrates a schematic fragmentary cross-sectional view of the structure 200 or the alternative structure (e.g., 200′, 200″) taken along line A-A′ as in FIG. 11. In some embodiments, the guard ring structure 254 disclosed herein is electrically connected to the discharging structure 228 by a path 268 or a path 270. The path 268 may connect the discharging structure 228 to the frontside conductive structure 220. For example, the direct contact of the extended metal line 226 and the discharging structure 228 in FIG. 7 corresponds to the path 268. In another example, the V0 via 266 in FIG. 9 corresponds to the path 268. The path 270 may connect the discharging structure to the backside conductive structure 240. For example, the direct contact of the extended metal line 226 and the discharging structure 228 in FIG. 10 corresponds to the path 270. The discharging structure 228 may be disposed in any suitable positions, such as the substrate 202, the ILD layer 214, the backside dielectric layer 232, and any level interconnect layer(s) (e.g., M0, V0, M1, . . . BM2, BV2, and BM3 levels) of the frontside interconnect structure and the backside interconnect structure. The discharging structure 228 may extend in more than one interconnect layers. The discharging structure 228 may be disposed in the substrate 202. The extended metal line 226 may be a metal line or a via at any level. The path 268 (or the path 270) connects the extended metal line 226 and the discharging structure 228 and may be disposed therebetween. The structure 200 may include additional features (e.g., metal lines, vias, devices) surrounded by the guard ring structure 254 other than the TSV 256.

Although not intended to be limiting, one or more embodiments of the present disclosure provide many benefits to a semiconductor device. For example, the present disclosure avoids charge accumulation in the guard ring structure. Thus, potential damages (e.g., PID) to the guard ring structure and PID to other devices may be avoided or reduced. In addition, TSV noises may be reduced, and TSV performance may be improved. Thus, the overall performance of the semiconductor device may be improved.

In one exemplary aspect, the present disclosure is directed to a semiconductor structure. The semiconductor structure includes a substrate, a dielectric structure including a plurality of dielectric layers, a ring structure disposed in the substrate and the dielectric structure, and a via structure extending lengthwise along a vertical direction and in a region surrounded by the ring structure. The plurality of dielectric layers include a plurality of frontside dielectric layers disposed on a front side of the substrate and a plurality of backside dielectric layers disposed on a back side of the substrate. The ring structure includes metal features disposed in the plurality of dielectric layers of the dielectric structure. In a top view, the ring structure has a ring pattern, and one of the metal features extends laterally beyond outer sidewalls of the ring pattern to be connected to a diode or a conductive via. The conductive via is connected to a first reference voltage.

In some embodiments, the first reference voltage is a ground or negative supply voltage. In some embodiments, the diode is connected to a second reference voltage by a via. In some embodiments, the second reference voltage is a ground or negative supply voltage. In some embodiments, the metal features include frontside metal features disposed in the plurality of frontside dielectric layers and backside metal features disposed in the plurality of backside dielectric layers, the frontside metal features are vertically stacked, the backside metal features are vertically stacked, the ring structure further includes front-end-of-line (FEOL) features and middle-end-of-line (MEOL) features connecting the frontside metal features and the backside metal features. In some embodiments, the diode is disposed in a same dielectric layer as the one of the metal features. In some embodiments, the one of the metal features is disposed in a first dielectric layer of the plurality of dielectric layers, the diode is disposed in a second dielectric layer of the plurality of dielectric layers, the second dielectric layer being closer to the substrate than the first dielectric layer. In some embodiments, the semiconductor structure further includes a via connecting the one of the metal features and the diode. In some embodiments, the semiconductor structure further includes a top metal line disposed in the dielectric structure and over the ring structure and the via structure, the top metal line is connected to the via structure and spaced apart from the ring structure.

In another exemplary aspect, the present disclosure is directed to a semiconductor structure. The semiconductor structure includes a substrate, a frontside dielectric structure disposed over the substrate and including a plurality of frontside dielectric layers, a backside dielectric structure disposed below the substrate and including a plurality of backside dielectric layers, and a ring structure including frontside conductive features, backside conductive features, and front-end-of-line (FEOL) features and middle-end-of-line (MEOL) features connecting the frontside conductive features and the backside conductive features. The frontside conductive features are disposed in the frontside dielectric structure. The backside conductive features are disposed in the backside dielectric structure. The ring structure is electrically connected to a reference voltage by a via or is electrically connected to a diode.

In some embodiments, the diode is disposed in the substrate, in the frontside dielectric structure, or in the backside dielectric structure. In some embodiments, the diode is further connected to a ground or negative supply voltage. In some embodiments, the reference voltage is a ground or negative supply voltage, and the ring structure is electrically connected to the reference voltage by the via and a metal line disposed in the frontside dielectric structure or the backside dielectric structure. In some embodiments, the semiconductor structure further includes a via structure extending in the frontside dielectric structure, the substrate, and the backside dielectric structure in a region enclosed by the ring structure in a top view. In some embodiments, the semiconductor structure further includes a bottom metal line disposed in the backside dielectric structure and below the ring structure and the via structure, the bottom metal line is connected to the via structure and spaced apart from the ring structure. In some embodiments, in a cross-sectional view, one frontside conductive feature of the frontside conductive features has a first width greater than widths of the other frontside conductive features, and the one frontside conductive feature is connected to the diode or the reference voltage.

In yet another exemplary aspect, the present disclosure is directed to a method. The method includes receiving a substrate, forming front-end-of-line (FEOL) features and frontside middle-end-of-line (MEOL) features over the substrate, and forming a frontside dielectric structure over the substrate. The frontside dielectric structure includes frontside dielectric layers. The method further includes forming frontside ring conductive features in the frontside dielectric structure and electrically connected to the FEOL features and the frontside MEOL features, forming a discharging structure in one of the frontside dielectric layers and connected to one of the frontside ring conductive features, forming backside MEOL features in and below the substrate and electrically connected to the FEOL features, forming a backside dielectric structure below the substrate, forming backside ring conductive features in the backside dielectric structure and electrically connected to the backside MEOL features, and forming a through via extending in the frontside dielectric structure, the substrate, and the backside dielectric structure. During the forming of the backside MEOL features and the backside ring conductive features, electrical charges are generated and discharged to the discharging structure. The through via is surrounded by the frontside ring conductive features and the backside ring conductive features in a top view.

In some embodiments, the discharging structure includes a diode, a conductive line connected to a ground or negative supply voltage, or both. In some embodiments, the method further includes before forming the backside dielectric structure, forming a top metal line in the frontside dielectric structure and above the frontside ring conductive features, and after forming the through via, forming a bottom metal line in the backside dielectric structure and below the backside ring conductive features. The through via is connected to the top metal line and the bottom metal line. In some embodiments, the frontside ring conductive features and the backside ring conductive features have an overlap in the top view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a dielectric structure comprising a plurality of dielectric layers, wherein the plurality of dielectric layers comprise a plurality of frontside dielectric layers disposed on a front side of the substrate and a plurality of backside dielectric layers disposed on a back side of the substrate;
a ring structure disposed in the substrate and the dielectric structure; and
a via structure extending lengthwise along a vertical direction and in a region surrounded by the ring structure,
wherein the ring structure comprises metal features disposed in the plurality of dielectric layers of the dielectric structure,
wherein in a top view, the ring structure has a ring pattern, and one of the metal features extends laterally beyond outer sidewalls of the ring pattern to be connected to a diode or a conductive via,
wherein the conductive via is connected to a first reference voltage.

2. The semiconductor structure of claim 1, wherein the first reference voltage is a ground or negative supply voltage.

3. The semiconductor structure of claim 1, wherein the diode is connected to a second reference voltage by a via.

4. The semiconductor structure of claim 3, wherein the second reference voltage is a ground or negative supply voltage.

5. The semiconductor structure of claim 1, wherein the metal features comprise frontside metal features disposed in the plurality of frontside dielectric layers and backside metal features disposed in the plurality of backside dielectric layers,
wherein the frontside metal features are vertically stacked,
wherein the backside metal features are vertically stacked,
wherein the ring structure further comprises front-end-of-line (FEOL) features and middle-end-of-line (MEOL) features connecting the frontside metal features and the backside metal features.

6. The semiconductor structure of claim 1, wherein the diode is disposed in a same dielectric layer as the one of the metal features.

7. The semiconductor structure of claim 1, wherein the one of the metal features is disposed in a first dielectric layer of the plurality of dielectric layers,
wherein the diode is disposed in a second dielectric layer of the plurality of dielectric layers, the second dielectric layer being closer to the substrate than the first dielectric layer.

8. The semiconductor structure of claim 7, further comprising a via connecting the one of the metal features and the diode.

9. The semiconductor structure of claim 1, further comprising a top metal line disposed in the dielectric structure and over the ring structure and the via structure,
wherein the top metal line is connected to the via structure and spaced apart from the ring structure.

10. A semiconductor structure, comprising:
a substrate;
a frontside dielectric structure disposed over the substrate and comprising a plurality of frontside dielectric layers;
a backside dielectric structure disposed below the substrate and comprising a plurality of backside dielectric layers; and
a ring structure comprising frontside conductive features, backside conductive features, and front-end-of-line (FEOL) features and middle-end-of-line (MEOL) features connecting the frontside conductive features and the backside conductive features,
wherein the frontside conductive features are disposed in the frontside dielectric structure,
wherein the backside conductive features are disposed in the backside dielectric structure, and
wherein the ring structure is electrically connected to a reference voltage by a via or is electrically connected to a diode.

11. The semiconductor structure of claim 10, wherein the diode is disposed in the substrate, in the frontside dielectric structure, or in the backside dielectric structure.

12. The semiconductor structure of claim 11, wherein the diode is further connected to a ground or negative supply voltage.

13. The semiconductor structure of claim 10, wherein the reference voltage is a ground or negative supply voltage, and
wherein the ring structure is electrically connected to the reference voltage by the via and a metal line disposed in the frontside dielectric structure or the backside dielectric structure.

14. The semiconductor structure of claim 10, further comprising a via structure extending in the frontside dielectric structure, the substrate, and the backside dielectric structure in a region enclosed by the ring structure in a top view.

15. The semiconductor structure of claim 14, further comprising a bottom metal line disposed in the backside dielectric structure and below the ring structure and the via structure,
wherein the bottom metal line is connected to the via structure and spaced apart from the ring structure.

16. The semiconductor structure of claim 10, wherein in a cross-sectional view, one frontside conductive feature of the frontside conductive features has a first width greater than widths of the other frontside conductive features, and
wherein the one frontside conductive feature is connected to the diode or the reference voltage.

17. A method, comprising:
receiving a substrate;
forming front-end-of-line (FEOL) features and frontside middle-end-of-line (MEOL) features over the substrate;
forming a frontside dielectric structure over the substrate, wherein the frontside dielectric structure comprises frontside dielectric layers;
forming frontside ring conductive features in the frontside dielectric structure and electrically connected to the FEOL features and the frontside MEOL features;
forming a discharging structure in one of the frontside dielectric layers and connected to one of the frontside ring conductive features;
forming backside MEOL features in and below the substrate and electrically connected to the FEOL features;
forming a backside dielectric structure below the substrate;
forming backside ring conductive features in the backside dielectric structure and electrically connected to the backside MEOL features, wherein during the forming of the backside MEOL features and the backside ring conductive features, electrical charges are generated and discharged to the discharging structure; and
forming a through via extending in the frontside dielectric structure, the substrate, and the backside dielectric structure, wherein the through via is surrounded by the frontside ring conductive features and the backside ring conductive features in a top view.

18. The method of claim 17, wherein the discharging structure comprises a diode, a conductive line connected to a ground or negative supply voltage, or both.

19. The method of claim 17, further comprising:
before forming the backside dielectric structure, forming a top metal line in the frontside dielectric structure and above the frontside ring conductive features; and
after forming the through via, forming a bottom metal line in the backside dielectric structure and below the backside ring conductive features,
wherein the through via is connected to the top metal line and the bottom metal line.

20. The method of claim 17, wherein the frontside ring conductive features and the backside ring conductive features have an overlap in the top view.
